(19) United States
(12) Patent Application Publication
(10) Pub. No.: US 2024/0319703 A1
(43) Pub. Date: Sep. 26, 2024

(54) INSPECTION MANAGEMENT SYSTEM, INSPECTION MANAGEMENT DEVICE, INSPECTION MANAGEMENT METHOD, AND PROGRAM

(71) Applicant: OMRON Corporation, Kyoto-shi, Kyoto (JP)

(72) Inventors: Hiroyuki MORI, Kyoto-shi, KYOTO (JP); Mayuko TANAKA, Kyoto-shi, KYOTO (JP)

(21) Appl. No.: 18/259,455

(22) PCT Filed: Mar. 8, 2021
(86) PCT No.: PCT/JP2021/009048

§ 371 Date: Jun. 27, 2023

(30) Foreign Application Priority Data
Jan. 20, 2021 (JP) 2021-007225

(51) Int. Cl. G05B 19/406

(52) U.S. Cl. CPC G05B 19/406; G05B 2219/37448

(57) ABSTRACT

An inspection management system manages, in a production line for a product including a plurality of processes, a final inspection for a product finished through the plurality of processes and a plurality of intermediate inspections before the final inspection. The production line includes a plurality of manufacturing apparatuses and a plurality of inspection apparatuses corresponding to the plurality of processes. The inspection management system includes an inspection data obtainer, an inspection result obtainer, and an inspection setting supporter that generates an inspection record diagram showing, as information about an inspection item in one of the plurality of intermediate inspections, a presence or an absence of a product determined defective in the final inspection and information identifying whether the product determined defective in the final inspection is determined defective under an inspection item in another of the plurality of intermediate inspections, and displays the inspection record diagram.

### FIELD

The present invention relates to a technique for inspecting products in a production line.

### BACKGROUND

A production line includes an intermediate process or a final process in which a product inspection apparatus is installed to, for example, detect defects or sort defective products. For example, a production line for component mounting boards typically includes a process for printing cream solder on a wiring board (printing), a process for mounting components on the printed board (mounting), and a process for heating the printed board with mounted components to solder the components to the board (reflowing), after each of which the board is inspected.

In such inspections, inspection criteria are to be set for determining whether a product is acceptable or detective and are maintained in a state referable from an inspection apparatus. However, inappropriate inspection criteria may cause acceptable products to be determined defective (false rejection) or defective products to be determined acceptable (false acceptance).

False rejection can lower the inspection efficiency by, for example, lowering the production yield or increasing the reinspection cost. False acceptance can lower the work efficiency in subsequent processes with, for example, repair work, or cause shipment of defective products. Both false rejection and false acceptance are thus to be minimized. However, stricter inspection criteria to reduce false acceptance can increase false rejection, and more lenient inspection details to reduce false rejection can increase false acceptance. Appropriate inspection criteria are thus to be set.

In the production line for component mounting boards described above, the inspection after reflowing finally determines whether a product is acceptable or defective (hereafter also referred to as a final inspection) whereas the inspection after each intermediate process before the final inspection (hereafter also referred to as an intermediate inspection) is typically a part of process management. In other words, intermediate inspections detect intermediate products that do not satisfy the quality level for each intermediate process (defective intermediate products) and prevent such defective intermediate products from being transferred to the subsequent processes to improve the production efficiency of the entire line or to check for any abnormality in the process in which defective intermediate products are detected.

In response to the above, inspection criteria for each process (e.g., a threshold for determining the acceptance of intermediate products) can be set based on the quality level of intermediate products intended by a user. Intermediate inspections thus typically have no clear method for determining inspection criteria. The criteria may be set leniently or strictly as intended by a user.

However, an intermediate product with a factor to be determined defective in the final inspection being determined acceptable in an intermediate inspection can lower the work efficiency in the subsequent processes. An intermediate product to be determined acceptable in the final inspection being determined defective in the intermediate inspection can also lower the inspection efficiency. Thus, inspection criteria are to be set to minimize inconsistent determination results between the intermediate inspection and the final inspection. In a product line including multiple inspections, a defective product being determined acceptable in every inspection before the final inspection is hereafter referred to as false acceptance, and a product to be determined acceptable in the final inspection being determined defective in at least one inspection before the final inspection is hereafter referred to as false rejection.

Known techniques include facilitating optimization of inspection criteria setting for such intermediate inspections (refer to, for example, Patent Literatures 1 to 4). For example, Patent Literatures 1 and 2 each describe a system that displays, in setting criteria for one intermediate inspection, a histogram showing, in different colors, the number of acceptable products and the number of defective products after the final inspection calculated for each interval of measurement values in an inspection item in the inspection, together with a line indicating an inspection criterion. Such determination results from the intermediate inspection for acceptable and defective products after the final inspection are displayed in an identifiable manner to allow a user with less experience to easily use the inspection criteria.

The inspection criteria set as described above allow appropriate detection of defective products in intermediate processes, thus increasing the percentage of acceptable products through repair or by reducing the number of discarded products (e.g., components or entire component mounting boards) resulting from defective products remaining in the final process.

To prevent final false acceptance in a production line with multiple intermediate processes, defects are to be detected in any of multiple inspections or under any of multiple inspection items. In other words, a defect detected under an inspection item in an intermediate inspection may not be detected under an inspection item in another intermediate inspection. Thus, an inspection criterion for an intermediate inspection item set to detect all defective products may cause many cases of false rejection. In this case, false rejection may be reduced by referring to the results of other intermediate inspection items and setting a more lenient inspection criterion.

### CITATION LIST

### Patent Literature

Patent Literature 1: Japanese Unexamined Patent Application Publication No. 2019-125693
Patent Literature 2: Japanese Unexamined Patent Application Publication No. 2019-125694
Patent Literature 3: Japanese Unexamined Patent Application Publication No. 2007-43009
Patent Literature 4: Japanese Unexamined Patent Application Publication No. 2006-317266

### SUMMARY

### Technical Problem

However, such known techniques involve, in setting inspection items in one intermediate inspection, highly complicated and impractical operations to refer to information about inspection results of inspection items in other intermediate inspections.

In response to the above circumstances, one or more aspects of the present invention are directed to a technique for efficiently and accurately setting inspection criteria for inspections in intermediate processes in a production line.

### Solution to Problem

The technique according to one or more aspects of the present invention provides the structure described below. An inspection management system manages, in a production line for a product including a plurality of processes, a final inspection for a product finished through the plurality of processes and a plurality of intermediate inspections before the final inspection. The production line includes a plurality of manufacturing apparatuses and a plurality of inspection apparatuses corresponding to the plurality of processes. The inspection management system includes a display that at least displays information about the plurality of intermediate inspections, an inspection data obtainer that obtains inspection data including an inspection criterion for an inspection item in each of the final inspection and the plurality of intermediate inspections for the product, an inspection result obtainer that obtains information including inspection results of the final inspection and the plurality of intermediate inspections, and an inspection setting supporter that generates an inspection record diagram showing, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections, and causes the display to display the inspection record diagram.

The final inspection described above includes visual inspection performed by human eyes, and the intermediate inspections include both the inspections of intermediate products that are yet to be final products and the inspections of final products by the inspection apparatuses before the visual inspection. In the production line including a process for assembling products and an inspection after assembly, the inspection after assembly may be the final inspection, and inspections before the final inspection may be the intermediate inspections. The inspection item in the other of the intermediate inspections may include an inspection item in an intermediate inspection after another process, in addition to another inspection item in the same intermediate inspection after the same process.

The inspection details herein may be inspection items for each product, inspection criteria for the inspection items (e.g., thresholds for determining whether a product is acceptable), and a process for determining whether to perform inspection with the corresponding inspection criterion for each item (hereafter also referred to as the on or off state of an inspection). The inspection data includes the current inspection details and potential new inspection details. The setting herein may be changing. The product herein may be an intermediate product or a finished product.

A system with the structure described above allows a user to easily set inspection criteria for excluding final products with actual defects that are to be excluded under one intermediate inspection item by referring to an inspection record diagram for information about the inspection results of other intermediate inspection items. This can lower the likelihood of the inspection accuracy being lowered by false rejection, thus improving the inspection efficiency.

The inspection record diagram may at least include an inspection reference line indicating a current inspection criterion. This structure allows intuitive determination of the relationship between the inspection results and the current inspection criteria, and thus facilitates evaluation of the inspection criteria performance.

The inspection record diagram may be a histogram. This structure allows easy determination as to whether a target intermediate inspection (or a target inspection item) can detect final products with actual defects, and whether acceptable products are determined defective (unintended defective determination results). For example, this structure allows easy determination of inefficiency in each inspection performed by determining whether the target intermediate inspection detects a defect detectable in another intermediate inspection or under another inspection item, or detects defective products that cause unintended defective determination results in any intermediate inspection or under any inspection item.

The inspection record diagram may be a scatter diagram. This structure allows easy determination as to whether the target intermediate inspection generates unintended defective determination results to detect final products with actual defects.

The inspection record diagram may identify, as the information about the inspection item in one of the plurality of intermediate inspections, a product determined acceptable in the final inspection, a product determined defective in the final inspection, and a product determined defective under the inspection item in the other of the plurality of intermediate inspections and in the final inspection in different colors.

The inspection setting supporter may cause the inspection record diagram to appear on a screen for setting inspection details of the plurality of intermediate inspections. This structure allows the setting of inspection details for the intermediate inspection performed by referring to the inspection record diagram of the target intermediate inspection and thus allows efficient operations.

Another aspect of the present invention may also be directed to an inspection management apparatus for managing, in a production line for a product including a plurality of processes, a final inspection for a product finished through the plurality of processes and a plurality of intermediate inspections before the final inspection. The production line includes a plurality of manufacturing apparatuses and a plurality of inspection apparatuses corresponding to the plurality of processes. The inspection managing apparatus includes an inspection data obtainer that obtains inspection data including an inspection criterion for an inspection item in each of the final inspection and the plurality of intermediate inspections for the product, an inspection result obtainer that obtains information including inspection results of the final inspection and the plurality of intermediate inspections, and an inspection setting supporter that generates an inspection record diagram showing, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections.

The final inspection, the intermediate inspections, and other inspection items in the intermediate inspections herein refer to the same as described above.

Another aspect of the present invention may also be directed to an inspection management method for managing, in a production line for a product including a plurality of processes, a final inspection for a product finished through the plurality of processes and a plurality of intermediate inspections before the final inspection. The production line includes a plurality of manufacturing apparatuses and a plurality of inspection apparatuses corresponding to the plurality of processes. The inspection management method includes obtaining inspection data including an inspection criterion for an inspection item in each of the final inspection and the plurality of intermediate inspections for the product, obtaining information including inspection results of the final inspection and the plurality of intermediate inspections, generating an inspection record diagram to show, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections, and outputting the generated inspection record diagram.

The final inspection, the intermediate inspections, and other inspection items in the intermediate inspections herein refer to the same as described above.

One or more aspects of the present invention may also be directed to a program for causing a computer to implement the method described above, or to a non-transitory computer-readable storage medium storing the program. The above structures and processes may be combined with one another unless any technical contradiction arises.

### Advantageous Effects

The technique according to the above aspects of the present invention can efficiently and accurately set inspection criteria for inspections in intermediate processes in a production line.

### BRIEF DESCRIPTION OF THE DRAWINGS

FIG. 1 is a schematic diagram of an inspection management system in an example use.

FIG. 2 is a functional block diagram of an inspection management apparatus in the example use.

FIG. 3 is an example inspection record diagram generated by the inspection management apparatus in the example use.

FIG. 4 is a schematic diagram of a production line according to an embodiment.

FIG. 5 is a functional block diagram of an inspection management apparatus according to the embodiment.

FIG. 6 is a flowchart showing processes for generating and displaying an inspection record diagram in the inspection management apparatus according to the embodiment.

FIG. 7 is an example inspection record diagram displayed on a display device according to the embodiment.

FIG. 8 is another example inspection record diagram displayed on a display device according to the embodiment.

### DETAILED DESCRIPTION

Embodiments of the present invention will now be described with reference to the drawings. The dimensions, materials, shapes, and relative positions of the components described in the embodiments do not intend to limit the scope of the present invention, unless otherwise specified.

### Example Use

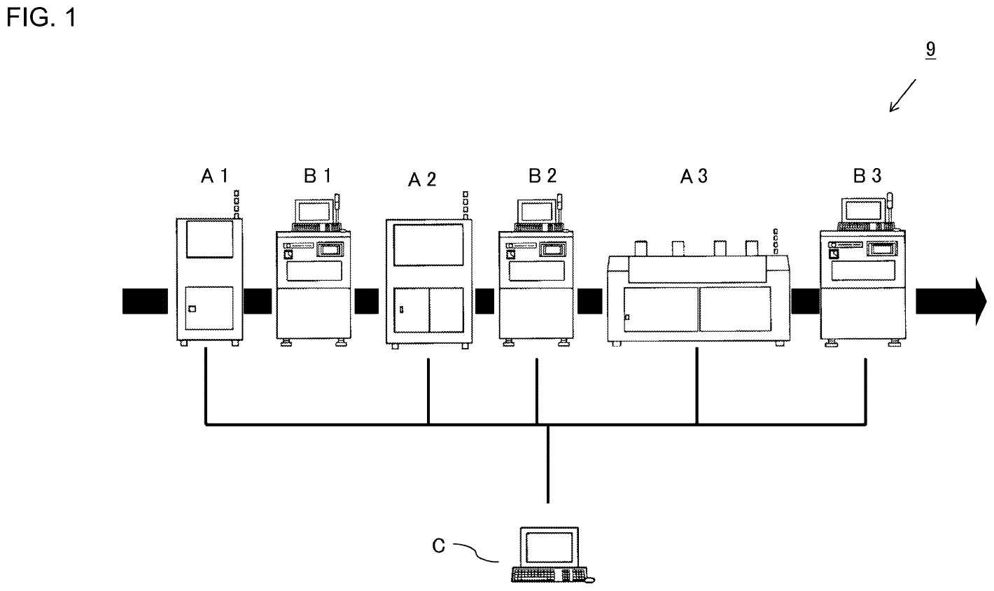

An inspection management system 9 according to one or more embodiments of the present invention is shown in FIG. 1. FIG. 1 is a schematic diagram of the inspection management system 9 in the present example use in a surface mounting line for printed circuit boards. As shown in FIG. 1, the surface mounting line in the present example use includes, in order from upstream, a solder printer A1, a post-solder printing inspection apparatus B1, a mounter A2, a post-mounting inspection apparatus B2, a reflow oven A3, and a post-reflowing inspection apparatus B3.

The solder printer A1 prints solder on electrodes on a printed circuit board. The mounter A2 mounts electronic components to be mounted on the board onto the solder paste. The reflow oven A3 heats and solders the electronic components on the board.

The inspection apparatuses B1, B2, and B3 each inspect the state of the board at the end of each process and automatically detect defects or any likelihood of defects. Inspection performed by the inspection apparatus B1 is hereafter referred to as a post-printing inspection. Inspection performed by the inspection apparatus B2 is referred to as a post-mounting inspection. Inspection performed by the inspection apparatus B3 is referred to as a post-reflowing inspection.

The manufacturing apparatuses A1, A2, and A3 and the inspection apparatuses B1, B2, and B3 described above are connected to an inspection management apparatus C with a network such as a local area network (LAN). The inspection management apparatus C includes a general-purpose computer system including a central processing unit (CPU, or processor), a main storage (memory), an auxiliary storage (e.g., a hard disk drive), input devices (e.g., a keyboard, a mouse, a controller, and a touch screen), and output devices (e.g., a display, a printer, and a speaker).

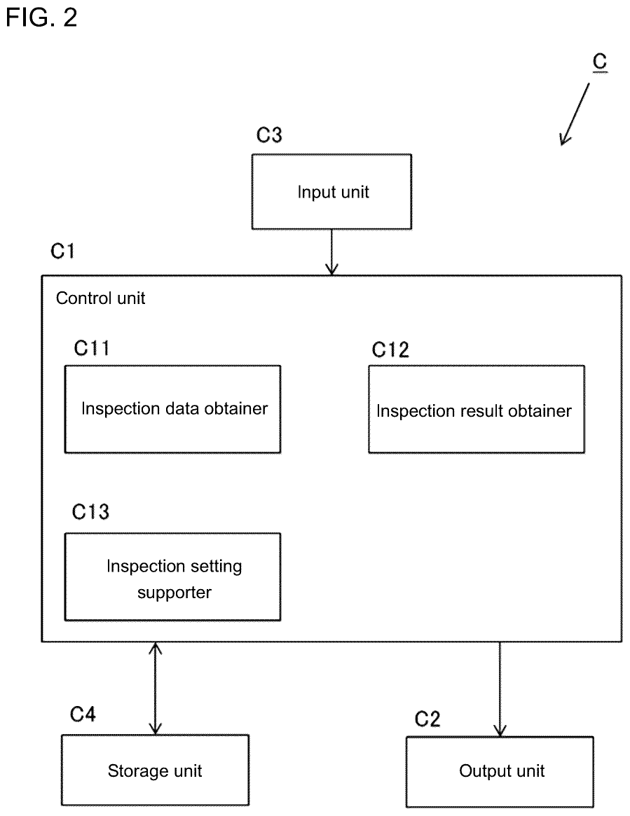

FIG. 2 is a schematic block diagram of the inspection management apparatus C according to the present example use. As shown in FIG. 2, the inspection management apparatus C includes a control unit C1, an output unit C2 (e.g., a liquid crystal display), an input unit C3, and a storage unit C4. The control unit C1 further includes, as functional modules, an inspection data obtainer C11, an inspection result obtainer C12, and an inspection setting supporter C13. Each functional module may be implemented by, for example, the CPU reading and executing a program stored in a storage.

The inspection data obtainer C11 obtains inspection data including inspection criteria for each inspection item in each process. The inspection result obtainer C12 obtains inspection result data including the result of each inspection from the inspection apparatuses B1, B2, and B3. The inspection setting supporter C13 generates an inspection record diagram based on the information obtained by the inspection data obtainer C11 and the inspection result obtainer C12, and displays the inspection record diagram on the output unit C2 as part of an inspection setting support screen. The inspection record diagram shows, as information about one inspection item in the intermediate inspections, the presence or absence of products determined defective in the final inspection and information identifying the products determined defective in the final inspection as being determined defective or acceptable under any of the other inspection items in the intermediate inspections.

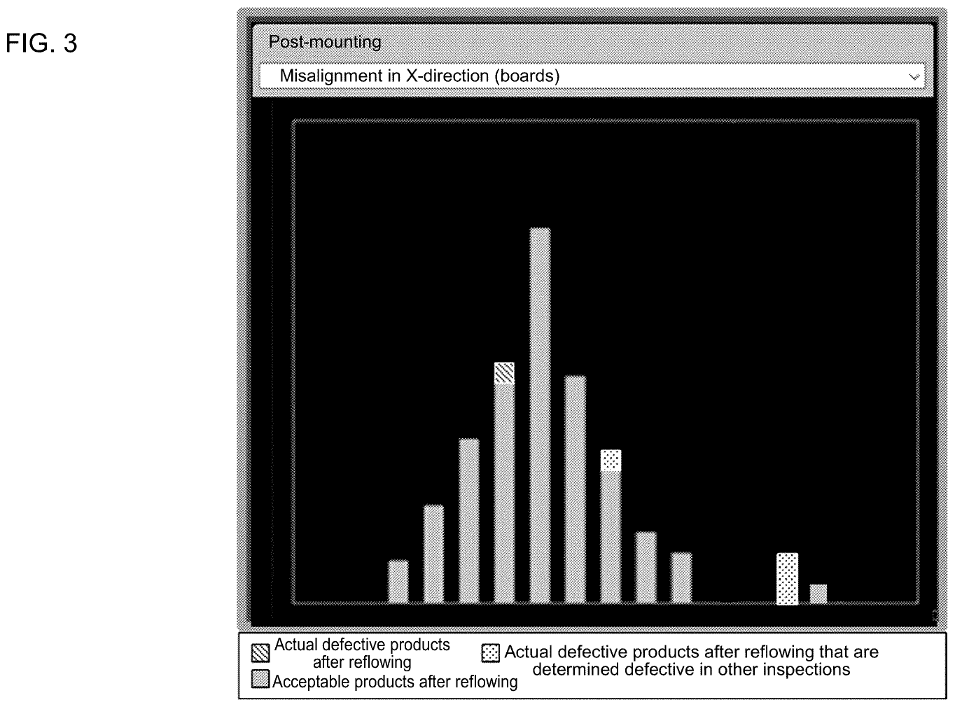

FIG. 3 is an example inspection record diagram in the present example use. As shown in FIG. 3, the inspection record diagram generated by the inspection setting supporter C13 is a histogram showing the number of acceptable products after reflowing and the number of actual defective products after reflowing calculated for each predetermined interval of measurement values for one inspection item (e.g., misalignment in X-direction) during one intermediate inspection (e.g., post-mounting inspection). The histogram identifies the number of acceptable products after reflowing, the number of actual defective products after reflowing, and the number of actual defective products after reflowing that are determined defective in other intermediate inspections (e.g., in the post-printing inspection).

In the example inspection record diagram in FIG. 3, the histogram includes bars displayed in different patterns (hatches, dots, and fills) each corresponding to actual defective products after reflowing, actual defective products after reflowing that are determined defective in other inspections, or acceptable products. The different determination results can thus be identified easily. Such a histogram is generated for each inspection item in each intermediate inspection.

The method for identifying defective or acceptable determination results is not limited to this, and the different determination results may be identified by, for example, differences in color or luminance. The inspection record diagram may also display an inspection reference line indicating the current inspection criterion.

The inspection management system 9 described above allows a user to efficiently set inspection criteria with high accuracy (in other words, criteria minimizing actual defective products and false rejection after reflowing) by referring to the inspection setting support screen.

### Embodiments

One embodiment of the present invention will now be described in more detail.

### System Configuration

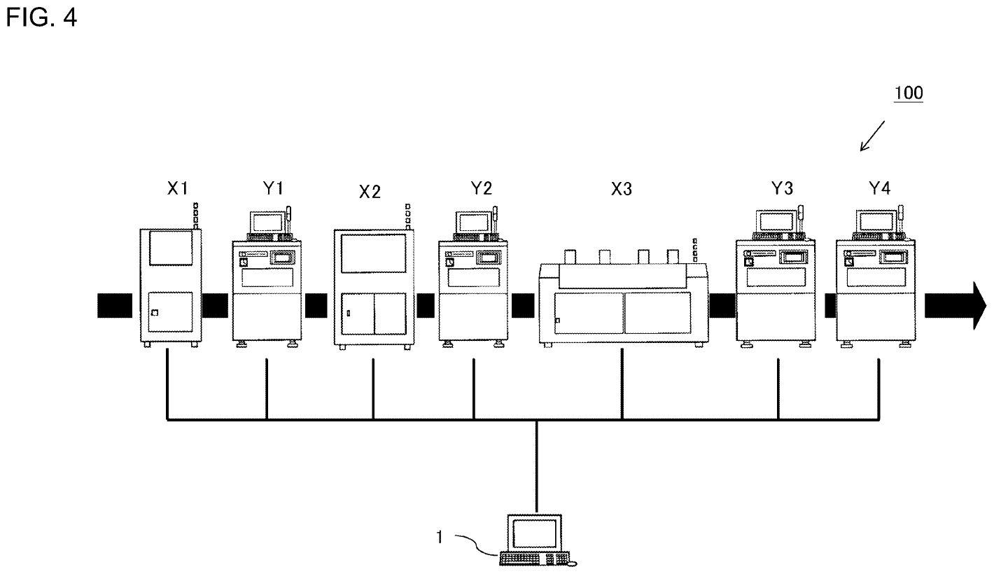

FIG. 4 is a schematic diagram of a surface mounting line for printed circuit boards as an inspection management system 100 according to the present embodiment, showing its example structure. Surface mount technology (SMT) is a technique for soldering an electronic component on a surface of a printed board and includes three main processes including solder printing, component mounting, and reflowing (solder melting).

The surface mounting line includes, as manufacturing apparatuses, a solder printer X1, a mounter X2, and a reflow oven X3 in order from upstream as shown in FIG. 4. The solder printer X1 prints a solder paste on electrodes (or lands) on a printed board by screen printing. The mounter X2, or a chip mounter, picks up an electronic component to be mounted on the board and mounts the component on the solder paste on the target portion. The reflow oven X3 heats and melts the solder paste, and then cools the solder paste to solder the electronic component on the board. The surface mounting line may include multiple mounters X2 when a large number of or various electronic components are to be mounted on the board.

The surface mounting line also includes inspection apparatuses Y1, Y2, Y3, and Y4 to inspect the state of the board at the end of each process and automatically detect defects or any likelihood of defects. Each inspection apparatus includes, in addition to the capability of automatically determining acceptable products and defective products, the capability of providing feedback to the operation of each manufacturing apparatus (e.g., to change a program for mounting) based on inspection results and their analysis.

The solder printing inspection apparatus Y1 inspects the state of the solder paste printed on the board unloaded from the solder printer X1. The solder printing inspection apparatus Y1 measures, two- or three-dimensionally, the solder paste printed on the board, and determines whether the measurement values fall within the range of normal values (tolerances) for various inspection items. The inspection items include the volume, surface area, height, positional deviation, and shape of the solder. The solder paste is measured two-dimensionally with, for example, an image sensor (camera), and three-dimensionally with, for example, a laser shift meter, a phase shifting method, a space-coding method, or a light-section method.

The post-mounting inspection apparatus Y2 inspects the placement of an electronic component on the board unloaded from the mounter X2. The post-mounting inspection apparatus Y2 measures, two- or three-dimensionally, the component (the component body or a part of the component such as an electrode) mounted on the solder paste, and determines whether the measurement values fall within the range of normal values (tolerances) for various inspection items. The inspection items include the positional deviation or angular (rotational) deviation of a component, a missing component (no component being placed), a component mix-up (a different component being placed), different polarities (the polarity of the component different from the polarity of the board), reversal of a component (a component being placed upside down), and the height of a component. As in the solder printing inspection, the electronic component is measured two-dimensionally with, for example, an image sensor (camera), and three-dimensionally with, for example, a laser shift meter, a phase shifting method, a space-coding method, or a light-section method.

The visual inspection apparatus Y3 inspects the condition of a solder joint on the board unloaded from the reflow oven X3. The visual inspection apparatus Y3 measures the post-reflowing solder two- or three-dimensionally, and determines whether the measurement values fall within the range of normal values (tolerances) for various inspection items. The inspection items include the shape of a solder fillet, in addition to the items used in the component inspection. The shape of solder is determined with, for example, a laser shift meter, a phase shifting method, a space-coding method, or a light-section method as described above, or also with a color highlight method (a method for determining the three-dimensional shape of solder with two-dimensional hue information by illuminating the solder surface with RGB color light at different angles of incidence and capturing the reflected light of each color using a top camera).

The X-ray inspection apparatus Y4 inspects the state of a solder joint on the board using an X-ray image. For example, a multilayer board or a package component, such as a ball grid array (BGA) and a chip size package (CSP), has solder joints hidden under the board or the component. In this structure, the state of the solder cannot be inspected with the visual inspection apparatus Y3 (or with an image of the product appearance). The X-ray inspection apparatus Y4 overcomes such weakness of visual inspection. The inspection items for the X-ray inspection apparatus Y4 include the positional deviation of a component, the height of solder, the volume of solder, the diameter of a solder ball, the length of a back fillet, and the condition of a solder joint. The X-ray image may be an image produced by projecting X-rays or an image produced using the computed tomography (CT) scan. In the example described below, the visual inspection apparatus Y3 and the X-ray inspection apparatus Y4 may be collectively referred to as the post-reflowing inspection apparatuses.

The inspection apparatuses Y1, Y2, Y3, and Y4 in the present embodiment may each include a display device for visual inspection of an inspection target. The display device for visual inspection may be a terminal separate from each inspection apparatus.

In the present embodiment, the board processed by the solder printer X1 and the mounter X2 is an intermediate product, and the board unloaded from the reflow oven X3 is a finished product. The inspections performed by the post-solder printing inspection apparatus Y1 and the component inspection apparatus Y2 are intermediate inspections. The inspections performed by the visual inspection apparatus Y3 and the X-ray inspection apparatus Y4 are final inspections. Hereafter, the inspection performed by the post-solder printing inspection apparatus Y1 may be referred to as a post-printing inspection, the inspection performed by the component inspection apparatus Y2 may be referred to as a post-mounting inspection, and the inspections performed by the visual inspection apparatus Y3 and the X-ray inspection apparatus Y4 may be referred to as post-reflowing inspections.

### (Production Management Apparatus)

The manufacturing apparatuses X1, X2, and X3 and the inspection apparatuses Y1, Y2, Y3, and Y4 described above are connected to an inspection management apparatus 1 with a network (LAN). The inspection management apparatus 1 is a system for managing and controlling the manufacturing apparatuses X1, X2, and X3 and the inspection apparatuses Y1, Y2, Y3, and Y4, and includes, although not shown, a general-purpose computer system including a CPU or processor, a main storage (memory), an auxiliary storage (e.g., a hard disk drive), input devices (e.g., a keyboard, a mouse, a controller, and a touch screen), and a display device. The functions of the inspection management apparatus 1 described below are implemented by the CPU reading programs stored in the auxiliary storage and executing the programs.

The inspection management apparatus 1 may include a single computer or multiple computers. All or some of the functions of the inspection management apparatus 1 may be implemented by a computer in any of the manufacturing apparatuses X1, X2, or X3 or the inspection apparatuses Y1, Y2, Y3, or Y4. Some of the functions of the inspection management apparatus 1 may be implemented by a server on a network (e.g., a cloud server).

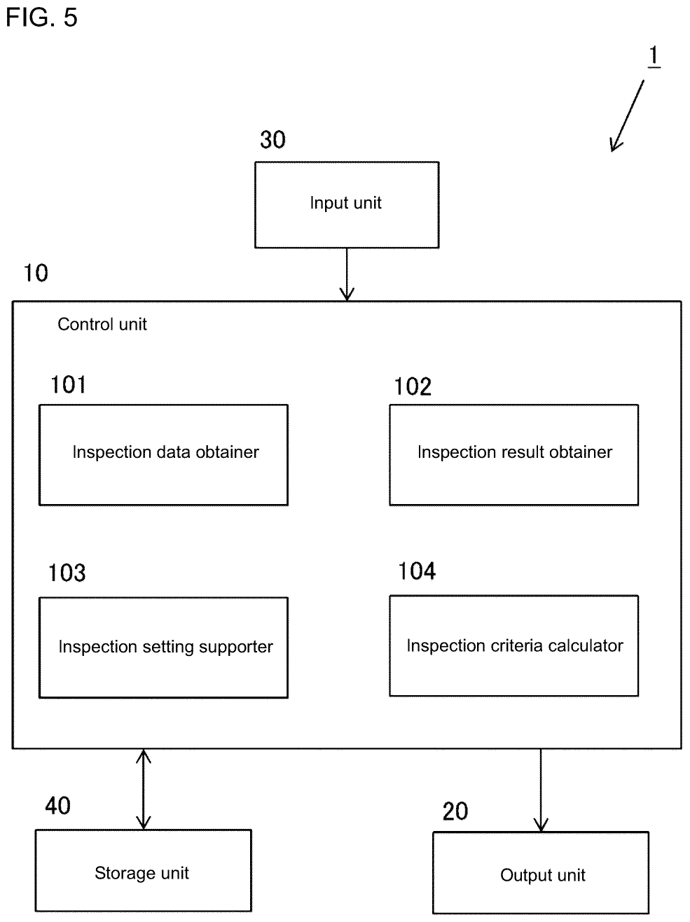

FIG. 5 is a functional block diagram of the inspection management apparatus 1 according to the present embodiment. As shown in FIG. 5, the inspection management apparatus 1 includes a control unit 10, an output unit 20, an input unit 30, and a storage unit 40. The control unit 10 further includes, as functional modules, an inspection data obtainer 101, an inspection result obtainer 102, an inspection setting supporter 103, and an inspection criteria calculator 104. Each function module may be implemented by, for example, the CPU reading and executing a program stored in a storage unit such as a main storage.

The output unit 20 outputs various sets of information including an inspection setting support screen (described later) and typically includes a display device such as a liquid crystal display. The output unit 20 being a display device may also output a user interface screen. The input unit 30 receives an input into the inspection management apparatus 1 and typically includes a keyboard, a mouse, a controller, and a touch screen.

The storage unit 40 stores various sets of information such as inspection data and inspection result data (described later). The storage unit 40 includes, for example, an external storage such as a server.

Each functional block in the control unit 10 will now be described. The inspection data obtainer 101 obtains data about inspection details including inspection criteria for each inspection item in each process. The inspection details herein include inspection items for each product, inspection criteria for the inspection items (e.g., thresholds for determining whether a product is acceptable), and a process for determining whether to perform inspection with the corresponding inspection criterion for each item (hereafter also referred to as the on or off state of an inspection). The inspection data includes the current inspection details and potential new inspection details. The inspection data may be obtained as values of inspection criteria calculated by the inspection criteria calculator 104 as described later, or as values input by a user through the input unit 30.

The inspection result obtainer 102 obtains inspection result data including the results of each inspection (determination results of being acceptable or defective) from the inspection apparatuses Y1, Y2, Y3, and Y4. The inspection setting supporter 103 generates an inspection record diagram based on the information obtained by the inspection data obtainer 101 and the inspection result obtainer 102, and displays the inspection record diagram on the output unit 20 as part of the inspection setting support screen.

The inspection criteria calculator 104 calculates inspection criteria that are more appropriate than the current inspection criteria for each inspection item in response to a user instruction or automatically at a predetermined timing. More specifically, inspection criteria that can reduce false acceptance, false rejection, or both are more appropriate than the current criteria. The inspection criteria can be calculated by, for example, conducting simulation inspections based on the current inspection criteria and inspection results from the inspection apparatuses Y1, Y2, Y3, and Y4.

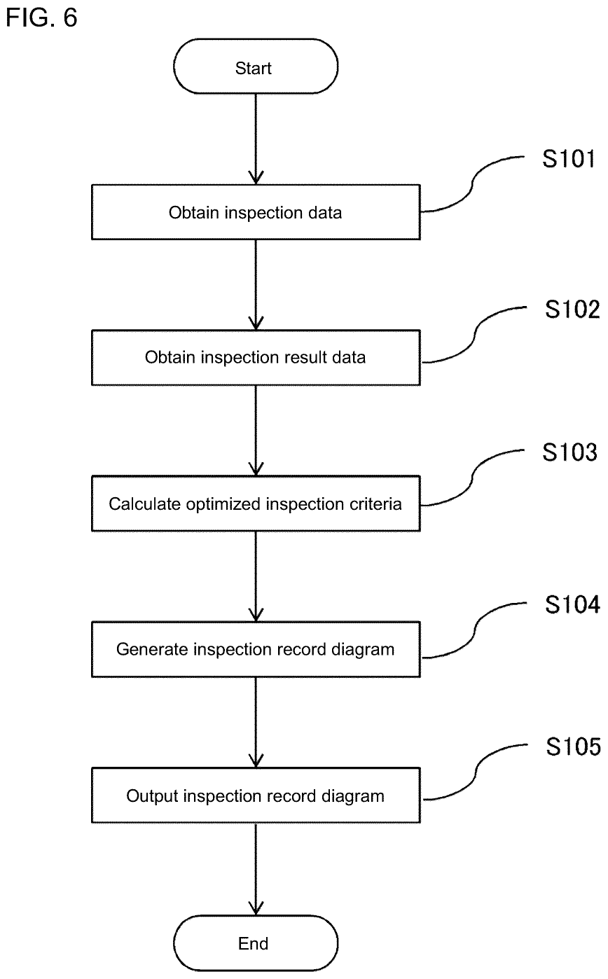

Processes for displaying the inspection setting support screen in the inspection management apparatus 1 according to the present embodiment are now described with reference to FIG. 6. In the inspection management apparatus 1, in response to, for example, a user instruction or a predetermined timing, the inspection data obtainer 101 obtains inspection data (S101), and the inspection result obtainer 102 obtains inspection result data (S102). The inspection criteria calculator 104 then calculates optimized inspection criteria for each inspection item based on the information obtained in steps S101 and S102 (step S103). Subsequently, the inspection setting supporter 103 generates an inspection record diagram based on the information obtained in steps S101 and S102 and the inspection criteria calculated in step S103 (S104), displays an inspection setting support screen including the inspection record diagram generated in step S104 on the output unit 20 (step S105), and ends the series of processes.

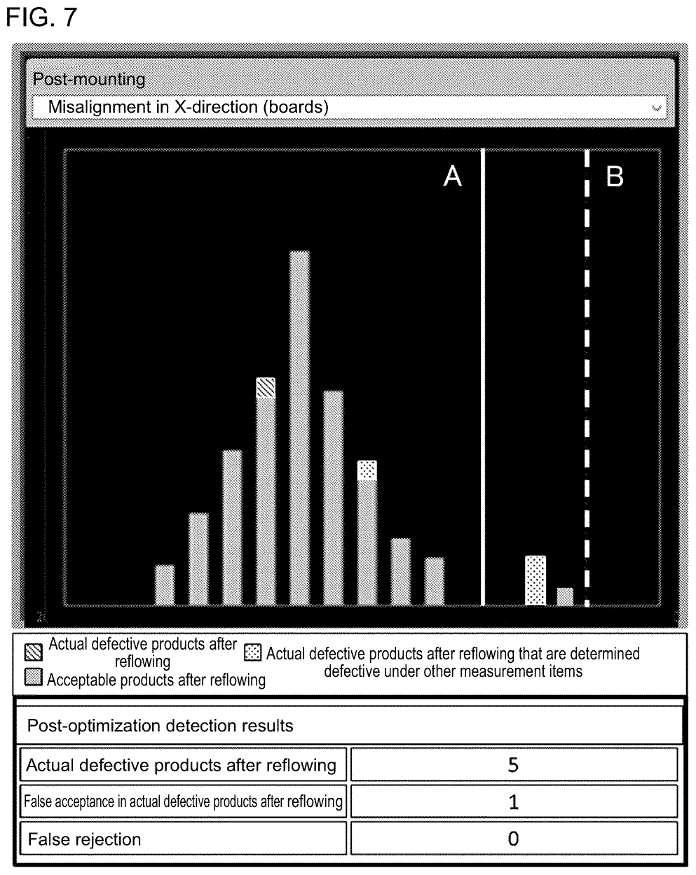

FIG. 7 is an example of an inspection setting support screen in the present embodiment. As shown in FIG. 7, an inspection record diagram on the inspection setting support screen shows a histogram showing the number of acceptable products after reflowing and the number of actual defective products after reflowing calculated for each predetermined interval of measurement values for an inspection item for misalignment in X-direction. The histogram identifies the number of acceptable products after reflowing, the number of actual defective products after reflowing, and the number of actual defective products after reflowing that are determined defective under other inspection items. The inspection record diagram also shows a current inspection reference line A indicating the current inspection criterion and an optimized inspection reference line B indicating an optimized inspection criterion calculated by the inspection criteria calculator 104 in a manner superimposed on the histogram.

The inspection setting support screen also displays, below the inspection record diagram, the number of acceptable products after reflowing, the number of actual defective products after reflowing, and the number of actual defective products after reflowing that are determined defective under other inspection items calculated based on the optimized inspection criterion.

### Advantageous Effects of Present Embodiment

The above structure allows a user to refer to the histogram (inspection record diagram) on an inspection setting screen and easily compare the optimized inspection criterion calculated by the inspection criteria calculator 104 with the current inspection criterion. The user can also easily determine whether an optimized inspection criterion can appropriately detect actual defective products after reflowing in a target intermediate inspection (or in a target inspection item) and whether the process causes unintended defective determination results. The user can determine the presence of unintended defective determination results by, for example, determining whether the target intermediate inspection detects a defect detectable in another intermediate inspection or under another inspection item, or detects defective products that cause unintended defective determination results in any intermediate inspection or under any inspection item.

More specifically, in the example shown in the inspection record diagram in FIG. 7, the current inspection criterion (that determines products on the left of the current inspection reference line A as acceptable) detects actual defective products after reflowing detectable under other inspection items and also causes false rejection by determining acceptable products after reflowing as defective. However, the optimized criterion calculated by the inspection criteria calculator 104 (that determines products on the left of the optimized inspection reference line B as acceptable) correctly determines false rejection products as acceptable. In this case, the optimized criterion determines the actual defective products after reflowing detectable by the current inspection criterion as acceptable. However, the user can determine that the products are determined defective under other inspection items and thus do not cause final false acceptance.

### Modifications

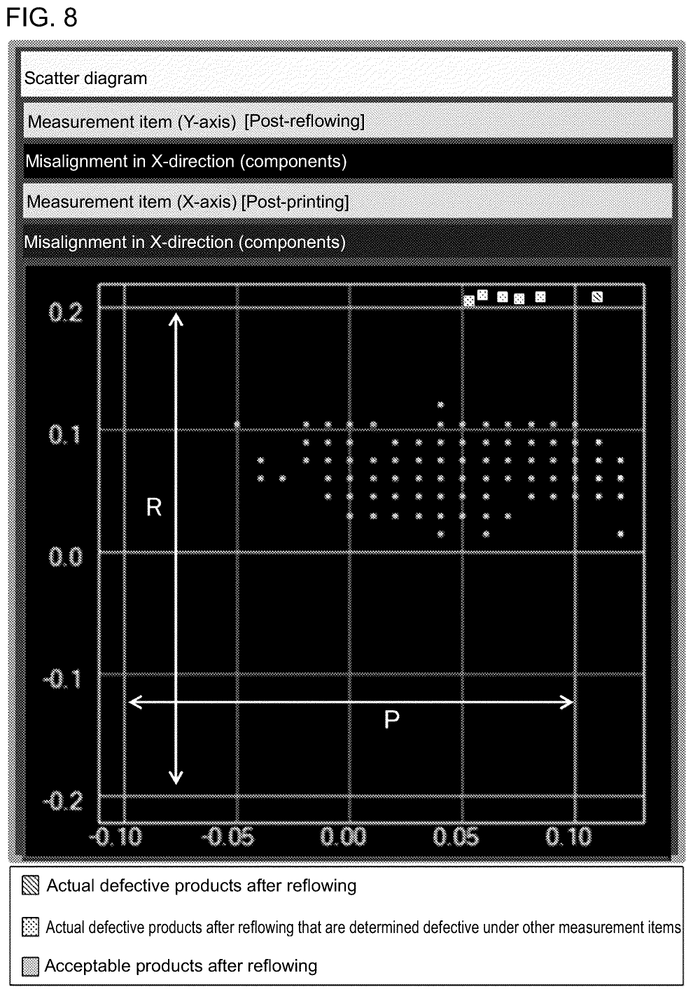

Although the inspection record diagram in the above embodiment is a histogram, the display format of the inspection record diagram is not limited to a histogram. FIG. 8 is another example of the inspection record diagram.

As shown in FIG. 8, the inspection record diagram in the present modification is a scatter diagram plotting inspection results, with X-axis indicating measurement values for an inspection item for component misalignment in X-direction in the post-printing inspection and Y-axis indicating measurement values for an inspection item for component misalignment in X-direction in the post-reflowing inspection. The scatter diagram identifies the number of acceptable products after reflowing, the number of actual defective products after reflowing, and the number of actual defective products after reflowing that are determined defective under other inspection items. Arrow R in the figure indicates the range of measurement values determined acceptable in the post-reflowing inspection. Arrow P in the figure indicates the range of measurement values determined acceptable in the post-printing inspection.

Such a scatter diagram as an inspection record diagram can be used to determine whether unintended defective determination results occur in an intermediate inspection to detect actual defective products after reflowing. Such a scatter diagram can also be used to determine whether other inspections and other inspection items appropriately cooperate with one another to detect actual defective products after reflowing and whether an inspection or an inspection item displayed in the diagram unintendedly detects actual defective products after reflowing.

A scatter diagram as an inspection record diagram may also show a current inspection reference line indicating the current inspection criterion, an optimized inspection reference line indicating an optimized inspection criterion, or both.

Highly accurate inspection criteria for a target inspection or a target inspection item can be set in referring to the scatter diagram when the correlation on the scatter diagram is high between measurement values for an intermediate inspection and measurement values for a post-reflowing inspection and actual defective products after reflowing are plotted along and at the ends of the distribution of the measurement values for each inspection.

The actual defective products after reflowing may not be detected with high accuracy when the correlation is low between the measurement values for the intermediate inspection and the measurement values for the post-reflowing inspection and the actual defective products after reflowing are plotted outside the distributions of these values. In other words, appropriate inspection details are not to be set by changing the inspection criteria for the inspection or the inspection item.

More specifically, for example, appropriate inspection details may not be set by changing inspection criteria when many products are plotted within the acceptable range in X-direction (measurement values for the post-printing inspection) but outside the acceptable range in Y-direction (measurement values for the post-reflowing inspection) as shown in the inspection record diagram in FIG. 8. In this case, many cases of false rejection may occur in the post-printing inspection when an inspection criterion for misalignment in X-direction in the post-printing inspection is adjusted to be stricter to reduce the number of actual defective products after reflowing. When many products are plotted outside the acceptable range in X-direction but near the center of the acceptable range in Y-direction, the post-printing inspection determines acceptable products as defective. In this case, more cases of false rejection may also occur.

Thus, a scatter diagram can be used to determine whether inspection accuracy can be improved by changing inspection criteria for an inspection or an inspection item targeted in an inspection criteria setting. More specifically, for example, inspection criteria for other inspections or inspection items may be optimized when many products determined defective in an intermediate inspection are determined acceptable with a sufficient margin in post-reflowing inspection criteria.

In the inspection record diagram in FIG. 8, for example, multiple products are plotted within the acceptable range in X-direction and outside the acceptable range in Y-direction, and many products are plotted outside the acceptable range in X-direction and within the acceptable range in Y-direction, indicating that determination of being acceptable or defective is inappropriate. The inspection record diagram in FIG. 8 can also be used to determine that products plotted outside the acceptable range in Y-direction are determined defective under other inspection items. Thus, the inspection accuracy is not to be improved by adjusting the inspection criterion for the currently referred inspection item, and the inspection criteria for other inspections or inspection items are to be optimized. The first pass rate in the intermediate inspections may be used to determine whether the inspection criterion is to be used when no other inspections or inspection items are more appropriate.

### Others

The above embodiments have been described by way of example, and the present invention is not limited to the specific embodiments described above. Various modifications may be made to the present invention within the scope of its technical idea. For example, the example inspection record diagrams in the above embodiments are a histogram and a scatter diagram, but the inspection record diagram may be in another format. For example, the inspection record diagram may be a stacked bar graph identifying, for each predetermined unit (e.g., time period), the number of acceptable products after the final inspection, the number of final actual defective products, and the number of final actual defective products that are determined defective under other inspection items.

The inspection setting supporter may generate both a histogram and a scatter diagram as inspection record diagrams (and other additional inspection record diagrams in other formats) and display the diagrams on the same screen. The inspection setting support screen may simultaneously display, in addition to inspection record diagrams, various sets of information such as information about components and an interface for inputting inspection details.

In the above embodiments, the post-reflowing inspection is the final inspection, and the post-printing and post-mounting inspection are the intermediate inspections. In some embodiments, the inspection performed by the X-ray inspection apparatus Y4 may be the final inspection, and the inspection performed by the visual inspection apparatus Y3 may be included in the intermediate inspections. A visual product inspection without an inspection apparatus may be the final inspection, and inspections with inspection apparatuses before the final inspection may be the intermediate inspections. When an inspection is conducted after product assembly, the inspection after assembly may be the final inspection, and inspections before the final inspection may be the intermediate inspections.

Although the inspection setting supporter in the above embodiments outputs a screen including an inspection record diagram on the display device, the inspection setting supporter may not have this structure and may simply generate data including an inspection record diagram to be displayed. The generated data may be transmitted to another device through a communicator or stored into the storage unit. In other words, the present invention is applicable to an information processing apparatus without a display.

The example production line in the above embodiments is for component mounting boards. However, the present invention is applicable to any production line with multiple intermediate processes for any products other than component mounting boards.

### Appendixes

An inspection management system according to one embodiment of the present invention is an inspection management system (9; 100) for managing, in a production line for a product including a plurality of processes, a final inspection for a product finished through the plurality of processes and a plurality of intermediate inspections before the final inspection, the production line including a plurality of manufacturing apparatuses and a plurality of inspection apparatuses corresponding to the plurality of processes, the inspection management system (9; 100) comprising:
a display (C2; 20) configured to at least display information about the plurality of intermediate inspections;
an inspection data obtainer (C11; 101) configured to obtain inspection data including an inspection criterion for an inspection item in each of the final inspection and the plurality of intermediate inspections for the product;
an inspection result obtainer (C12; 102) configured to obtain information including inspection results of the final inspection and the plurality of intermediate inspections; and
an inspection setting supporter (C13; 103) configured to generate an inspection record diagram showing, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections, and to cause the display to display the inspection record diagram.

An inspection management apparatus according to another embodiment of the present invention is an inspection management apparatus (C; 1) for managing, in a production line for a product including a plurality of processes, a final inspection for a product finished through the plurality of processes and a plurality of intermediate inspections before the final inspection, the production line including a plurality of manufacturing apparatuses and a plurality of inspection apparatuses corresponding to the plurality of processes, the inspection managing apparatus (C; 1) comprising:
an inspection data obtainer (C11; 101) configured to obtain inspection data including an inspection criterion for an inspection item in each of the final inspection and the plurality of intermediate inspections for the product;
an inspection result obtainer (C12; 102) configured to obtain information including inspection results of the final inspection and the plurality of intermediate inspections; and
an inspection setting supporter (C13; 103) configured to generate an inspection record diagram showing, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections.

An inspection management method according to still another embodiment of the present invention is an inspection management method for managing, in a production line for a product including a plurality of processes, a final inspection for a product finished through the plurality of processes and a plurality of intermediate inspections before the final inspection, the production line including a plurality of manufacturing apparatuses and a plurality of inspection apparatuses corresponding to the plurality of processes, the inspection management method comprising:
(S101) obtaining inspection data including an inspection criterion for an inspection item in each of the final inspection and the plurality of intermediate inspections for the product;
(S102) obtaining information including inspection results of the final inspection and the plurality of intermediate inspections;
(S104) generating an inspection record diagram to show, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections; and
(S105) outputting the generated inspection record diagram.

### DESCRIPTION OF SYMBOLS

A1, X1 solder printer
A2, X2 mounter
A3, X3 reflow oven
B1, Y1 post-solder printing inspection apparatus
B2, Y2 post-mounting inspection apparatus
B3 post-reflowing inspection apparatus
Y3 visual inspection apparatus
Y4 X-ray inspection apparatus
C, 1 inspection management apparatus
C1, 10 control unit
C2, 20 output unit
C3, 30 input unit
C4, 40 storage unit

1. An inspection management system for managing, in a production line for a product including a plurality of processes, a final inspection for a product finished through the plurality of processes and a plurality of intermediate inspections before the final inspection, the production line including a plurality of manufacturing apparatuses and a plurality of inspection apparatuses corresponding to the plurality of processes, the inspection management system comprising:
a display configured to at least display information about the plurality of intermediate inspections;
an inspection data obtainer configured to obtain inspection data including an inspection criterion for an inspection item in each of the final inspection and the plurality of intermediate inspections for the product;
an inspection result obtainer configured to obtain information including inspection results of the final inspection and the plurality of intermediate inspections; and
an inspection setting supporter configured to generate an inspection record diagram showing, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections, and to cause the display to display the inspection record diagram.

2. The inspection management system according to claim 1, wherein
the inspection record diagram at least includes an inspection reference line indicating a current inspection criterion.

3. The inspection management system according to claim 1, wherein
the inspection record diagram is a histogram or a scatter diagram.

4. The inspection management system according to claim 1, wherein
the inspection record diagram identifies, as the information about the inspection item in one of the plurality of intermediate inspections, a product determined acceptable in the final inspection, a product determined defective in the final inspection, and a product determined defective under the inspection item in the other of the plurality of intermediate inspections and in the final inspection in different colors.

5. The inspection management system according to claim 1, wherein
the inspection setting supporter causes the inspection record diagram to appear on a screen for setting inspection details of the plurality of intermediate inspections.

6. An inspection management apparatus for managing, in a production line for a product including a plurality of processes, a final inspection for a product finished through the plurality of processes and a plurality of intermediate inspections before the final inspection, the production line including a plurality of manufacturing apparatuses and a plurality of inspection apparatuses corresponding to the plurality of processes, the inspection managing apparatus comprising:
an inspection data obtainer configured to obtain inspection data including an inspection criterion for an inspection item in each of the final inspection and the plurality of intermediate inspections for the product;
an inspection result obtainer configured to obtain information including inspection results of the final inspection and the plurality of intermediate inspections; and
an inspection setting supporter configured to generate an inspection record diagram showing, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections.

7. An inspection management method for managing, in a production line for a product including a plurality of processes, a final inspection for a product finished through the plurality of processes and a plurality of intermediate inspections before the final inspection, the production line including a plurality of manufacturing apparatuses and a plurality of inspection apparatuses corresponding to the plurality of processes, the inspection management method comprising:
obtaining inspection data including an inspection criterion for an inspection item in each of the final inspection and the plurality of intermediate inspections for the product;
obtaining information including inspection results of the final inspection and the plurality of intermediate inspections;
generating an inspection record diagram to show, as information about an inspection item in one of the plurality of intermediate inspections, a presence or an absence of a product determined defective in the final inspection and information identifying the product determined defective in the final inspection as being determined defective or acceptable under an inspection item in another of the plurality of intermediate inspections; and
outputting the generated inspection record diagram.

8. A non-transitory computer readable medium storing a program for causing an information processing apparatus to perform operations included in the inspection management method according to claim 7.
